(19) United States
(12) Patent Application Publication
(10) Pub. No.: US 2026/0132500 A1
(43) Pub. Date: May 14, 2026

(54) SUBSTRATE PROCESSING DEVICE AND CONTROL METHOD OF SUBSTRATE PROCESSING DEVICE

(71) Applicant: SCREEN Holdings Co., Ltd., Kyoto (JP)

(72) Inventors: Takashi IZUTA, Kyoto (JP); Yasuhiko NAGAI, Kyoto (JP); Yusuke SEKI, Kyoto (JP); Yosuke NISHINO, Kyoto (JP); Kenji EDAMITSU, Kyoto (JP)

(21) Appl. No.: 19/377,379

(22) Filed: Nov. 3, 2025

(30) Foreign Application Priority Data
Nov. 12, 2024 (JP) 2024-197590

(51) Int. Cl. C23C 14/54; C23C 14/58

(52) U.S. Cl. CPC C23C 14/54; C23C 14/5806

(57) ABSTRACT

To stabilize the solvent concentration of a solvent vapor supplied to a chamber. A controller included in a substrate processing device carries out: a gas supply process of controlling a pressure control regulator based on a pressure measured by a pressure sensor measuring the pressure inside a vapor generation tank, to regulate the flow rate of an inert gas supplied through a first inert gas supply pipe to the vapor generation tank in which a solvent is stored, and to stop the supply of the inert gas when the pressure measured by the pressure sensor reaches a target value; and a vapor supply process of supplying the solvent vapor from the vapor generation tank to the chamber through a gas supply pipe after the supply of the inert gas is stopped.

### TECHNICAL FIELD

This Nonprovisional application claims priority under 35 U.S.C. § 119 on Patent Application No. 2024-197590 filed in Japan on Nov. 12, 2024, the entire contents of which are hereby incorporated by reference.

The present invention relates to a substrate processing device that processes, with a processing liquid, various substrates, such as semiconductor wafers, glass substrates for liquid crystal displays (LCDs), glass substrates for plasma displays (PDPs), glass/ceramic substrates for magnetic/optical disks, and substrates for electronic devices, and subsequently dries the substrates using a solvent vapor, and relates to a control method thereof.

### BACKGROUND ART

Patent Literature 1 discloses a processing chamber for processing a wafer, and a substrate processing device in which an inert gas is supplied to a liquid material filled in a tank so as to vaporize the liquid material, and the resulting vaporized gas is supplied into the processing chamber to form a film on the wafer. In Patent Literature 1, a controller of the substrate processing device constantly monitors the absolute pressure inside the tank by means of a pressure sensor. The controller regulates the flow rate of the inert gas supplied to the tank based on the monitored pressure value, so that the absolute pressure inside the tank reaches a target value.

### CITATION LIST

### Patent Literature

[Patent Literature 1]

Japanese Patent Application Publication, Tokukai, No. 2012-9744

### SUMMARY OF INVENTION

### Technical Problem

In a substrate processing device in which a substrate that has been processed with a processing liquid inside a chamber is dried using a solvent vapor, variations may occur in the solvent concentration of the solvent vapor supplied into the chamber. A possible cause for this is that the pressure inside the vapor generation tank, which generates the vapor of the solvent, is susceptible to the influence of atmospheric pressure. When the pressure in the vapor generation tank varies due to the influence of atmospheric pressure, a pressure difference arises between the pressure inside the chamber and the pressure inside the vapor generation tank. Due to this pressure difference, it is considered that variations occur in the solvent concentration of the solvent vapor supplied into the chamber.

The substrate processing device disclosed in Patent Literature 1 supplies, into the processing chamber, the vaporized gas obtained by vaporizing the liquid material inside the tank, while controlling the absolute pressure inside the tank. Thus, when the absolute pressure inside the tank is regulated while supplying the vaporized gas into the processing chamber, it is conceivable that the absolute pressure inside the tank may temporarily deviate significantly from the target value. In this case, it is considered that variations occur in the solvent concentration of the solvent vapor supplied into the chamber.

An object of an aspect of the present invention is to stabilize the solvent concentration of a solvent vapor supplied to a chamber.

### Solution to Problem

To achieve the object, a substrate processing device in accordance with an aspect of the present invention is a substrate processing device configured to dry, using a solvent vapor, a substrate processed with a processing liquid, the substrate processing device including: a processing tank configured to store a processing liquid; a chamber enclosing the processing tank; a pressure reduction device configured to discharge a gas inside the chamber to reduce pressure inside the chamber; a vapor generation tank configured to store a solvent and to generate vapor of the solvent as the solvent vapor; a first supply pipe connecting the chamber and the vapor generation tank; a second supply pipe connecting the vapor generation tank and a gas supply source configured to supply an inert gas to the vapor generation tank; a pressure sensor configured to measure pressure inside the vapor generation tank; a regulator configured to regulate flow rate of the inert gas supplied to the vapor generation tank; and a controller, the controller being configured to carry out: a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and a vapor supply process of supplying the solvent vapor from the vapor generation tank to the chamber through the first supply pipe after the supply of the inert gas is stopped.

To achieve the object, a control method of a substrate processing device in accordance with an aspect of the present invention is a control method of a substrate processing device configured to dry, using a solvent vapor, a substrate processed with a processing liquid, the substrate processing device including: a processing tank configured to store a processing liquid; a chamber enclosing the processing tank; a pressure reduction device configured to discharge a gas inside the chamber to reduce pressure inside the chamber; a vapor generation tank configured to store a solvent and to generate vapor of the solvent as the solvent vapor; a first supply pipe connecting the chamber and the vapor generation tank; a second supply pipe connecting the vapor generation tank and a gas supply source configured to supply an inert gas to the vapor generation tank; a pressure sensor configured to measure pressure inside the vapor generation tank; and a regulator configured to regulate flow rate of the inert gas supplied to the vapor generation tank, the method including: a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and a vapor supply process of supplying the solvent vapor from the vapor generation tank to the chamber through the first supply pipe after the supply of the inert gas is stopped.

### Advantageous Effects of Invention

According to an aspect of the present invention, it is possible to stabilize the solvent concentration of a solvent vapor supplied to a chamber.

### BRIEF DESCRIPTION OF DRAWINGS

FIG. 1 is a schematic diagram schematically illustrating the configuration of a substrate processing device.

FIG. 2 is a block diagram illustrating the configuration of the substrate processing device.

FIG. 3 is a diagram for explaining the operation of the substrate processing device.

FIG. 4 is a diagram for explaining the operation of the substrate processing device.

FIG. 5 is a graph showing the results of an experiment to regulate the pressure inside a vapor generation tank.

FIG. 6 is a graph showing the results of an experiment to regulate the pressure inside the vapor generation tank.

FIG. 7 is a graph showing the pressure changes inside the vapor generation tank.

FIG. 8 is a graph showing the pressure changes inside the vapor generation tank.

### DESCRIPTION OF EMBODIMENTS

### Embodiment 1

The following description will discuss an embodiment of the present disclosure in detail.

### [Outline of Substrate Processing Device]

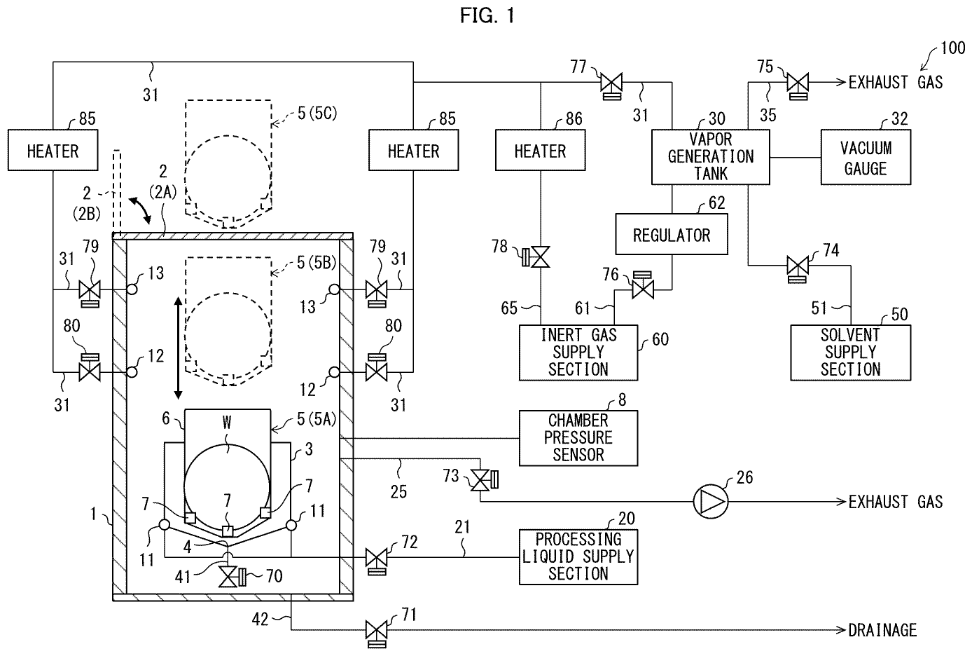

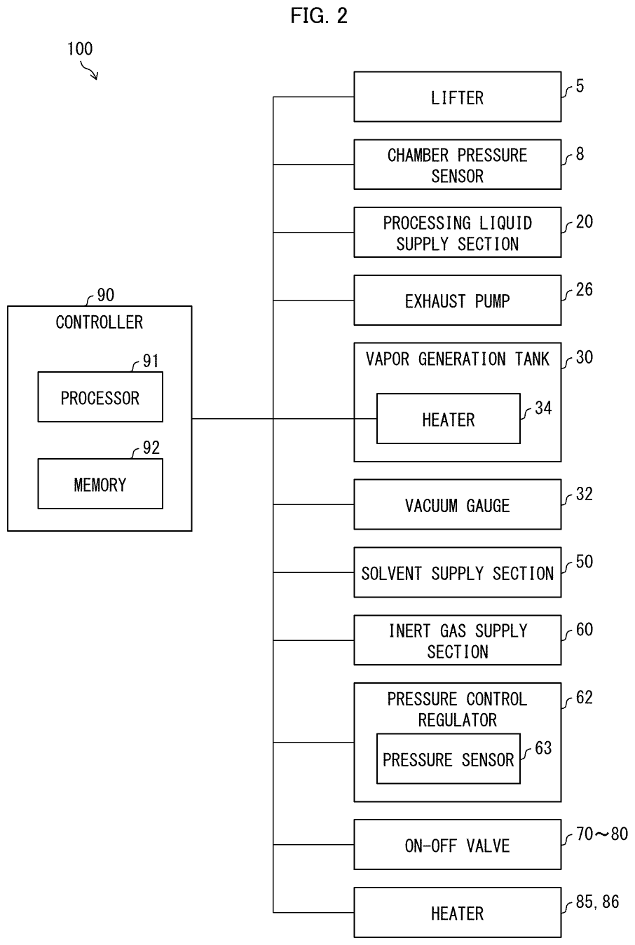

The following description will schematically discuss the configuration of a substrate processing device 100 with reference to FIGS. 1 and 2. FIG. 1 is a schematic diagram schematically illustrating the configuration of the substrate processing device 100. FIG. 2 is a block diagram illustrating the configuration of the substrate processing device 100. The substrate processing device 100 is a device that dries, using a solvent vapor, a substrate W, which has been processed with a processing liquid. The substrate W may be, for example, a semiconductor substrate such as a silicon wafer.

As illustrated in FIG. 1, the substrate processing device 100 includes a chamber 1, a processing tank 3, and a lifter 5. The chamber 1 encloses the processing tank 3 that stores the processing liquid. An opening/closing lid 2 is arranged on top of the chamber 1 to open and close an opening formed at the upper part of the chamber 1. The opening/closing lid 2 is movable between a closed position 2A, where it blocks the opening formed at the upper part of the chamber 1, and an open position 2B, where it allows the opening to remain uncovered.

The processing tank 3 is provided with a nozzle 11. The nozzle 11 is connected to a processing liquid supply pipe 21, which is provided with an on-off valve 72. The nozzle 11 is supplied with the processing liquid from a processing liquid supply section 20 through the processing liquid supply pipe 21. When driven by a driving section (not illustrated), the processing liquid supply section 20 supplies the processing liquid from a tank (not illustrated) that stores the processing liquid to the processing liquid supply pipe 21. When the on-off valve 72 is in an open state, this allows the processing liquid to be supplied to the nozzle 11 through the processing liquid supply pipe 21. When the on-off valve 72 is in a closed state, this prevents the processing liquid from being supplied to the nozzle 11 through the processing liquid supply pipe 21. In the processing liquid stored in the processing tank 3, the substrate W, which is moved up and down by the lifter 5, is immersed.

At a lower part of the processing tank 3, a discharge port 4 is formed to discharge the processing liquid inside the processing tank 3 to the outside of the processing tank 3. The discharge port 4 is connected to a discharge pipe 41 provided with an on-off valve 70. The processing liquid inside the processing tank 3 is discharged to the bottom of the chamber 1 through the discharge pipe 41 when the on-off valve 70 is in an open state, and is not discharged to the bottom of the chamber 1 through the discharge pipe 41 when the on-off valve 70 is in a closed state. At the bottom of the chamber 1, a drainage pipe 42 provided with an on-off valve 71 is connected. A liquid accumulated in the bottom of the processing tank 1 is discharged to the outside of the chamber 1 through the drainage pipe 42 when the on-off valve 71 is in an open state, and is not discharged to the outside of the chamber 1 through the drainage pipe 42 when the on-off valve 71 is in a closed state.

The lifter 5 is a mechanism for raising and lowering the substrate W with respect to the chamber 1. The lifter 5 includes a back plate 6 and a substrate support section 7. The back plate 6 is a vertically extending member, and the substrate support section 7 is attached to the lower part of the back plate 6. The substrate support section 7 is a component that supports the substrate W from below. By fitting the substrate W into one or more grooves formed in the substrate support section 7, the substrate support section 7 supports the substrate W from below. The substrate support section 7 supports one or more substrates W.

The lifter 5 moves the back plate 6 vertically by the driving force from a driving section (not illustrated). As the back plate 6 moves vertically, the substrate W supported by the substrate support section 7 is raised and lowered within the chamber 1. The lifter 5 is movable to a dipping position 5A, a drying position 5B, and a retrieval position 5C. The dipping position 5A is a position where the substrate W, supported by the substrate support section 7, is immersed in the processing liquid stored in the processing tank 3. The drying position 5B is a position where the substrate W, supported by the substrate support section 7, is located inside the chamber 1 and outside the processing tank 3. The drying position 5B is located inside the chamber 1 and above the dipping position 5A. The retrieval position 5C is a position where the substrate W, supported by the substrate support section 7, is located outside the chamber 1.

The chamber 1 is provided with a chamber pressure sensor 8 that measures the pressure inside the chamber 1. The pressure inside the chamber 1 is controlled based on the pressure measured by the chamber pressure sensor 8.

The chamber 1 is provided with a nozzle 12 and a nozzle 13. The nozzles 12 and 13 are nozzles that discharge a solvent vapor or an inert gas into the interior of the chamber 1. The nozzles 12 and 13 are each provided at the upper part of the chamber 1. The nozzle 13 is positioned above the nozzle 12. The nozzles 12 and 13 are each connected to the gas supply pipe 31.

The gas supply pipe 31 is provided with a heater 85, an on-off valve 79, and an on-off valve 80. The heater 85 heats the interior of the gas supply pipe 31 and regulates the temperature of the solvent vapor or the inert gas discharged from the nozzles 12 and 13. The on-off valve 79 is located in the gas supply pipe 31 between the heater 85 and the nozzle 13. When the on-off valve 79 is in an open state, this allows the nozzle 13 to discharge the solvent vapor or the inert gas, and when the on-off valve 79 is in a closed state, this prevents the nozzle 13 from discharging the solvent vapor or the inert gas. The on-off valve 80 is located in the gas supply pipe 31 between the heater 85 and the nozzle 12. When the on-off valve 80 is in an open state, this allows the nozzle 12 to discharge the solvent vapor or the inert gas, and when the on-off valve 80 is in a closed state, this prevents the nozzle 12 from discharging the solvent vapor or the inert gas.

To the chamber 1, a chamber exhaust pipe 25, which is provided with an exhaust pump 26 and an on-off valve 73, is connected. The exhaust pump 26 discharges a gas inside the chamber 1 through the chamber exhaust pipe 25 to reduce the pressure inside the chamber 1. The exhaust pump 26 is an example of a pressure reduction device. When the on-off valve 73 is in an open state, this allows the exhaust pump 26 to discharge a gas from the chamber 1. When the on-off valve 73 is in a closed state, this prevents the exhaust pump 26 from discharging a gas from the chamber 1.

The substrate processing device 100 includes the vapor generation tank 30 and the gas supply pipe 31. The vapor generation tank 30 is a tank that stores a solvent and generates vapor of the solvent as the solvent vapor. The gas supply pipe 31 connects the chamber 1 and the vapor generation tank 30. The gas supply pipe 31 is an example of a first supply pipe. The gas supply pipe 31 is provided with an on-off valve 77. The on-off valve 77 is provided in the gas supply pipe 31 upstream of the connection point where a second inert gas supply pipe 65, which will be described later, and the gas supply pipe 31 are connected. When the on-off valve 77 is in an open state, this allows a solvent vapor generated in the vapor generation tank 30 to be supplied to the chamber 1 through the gas supply pipe 31. When the on-off valve 77 is in a closed state, this prevents the solvent vapor generated in the vapor generation tank 30 from being supplied to the chamber 1 through the gas supply pipe 31.

The vapor generation tank 30 is provided with a vacuum gauge 32. The vacuum gauge 32 measures the pressure inside the vapor generation tank 30. More specifically, the vacuum gauge 32 determines the difference between the pressure inside the vapor generation tank 30 measured by itself and the absolute pressure inside the vapor generation tank 30 measured by a pressure sensor 63, which will be described later. As illustrated in FIG. 2, the vapor generation tank 30 is provided with a heater 34. The heater 34 heats the interior of the vapor generation tank 30. The heater 34 is an example of a heating device. The heater 34 regulates the temperature of the interior of the vapor generation tank 30.

Returning to FIG. 1, the substrate processing device 100 includes a solvent supply pipe 51. The solvent supply pipe 51 is an example of the third supply pipe. The solvent supply pipe 51 connects the vapor generation tank 30 and a solvent supply section 50 serving as a solvent supply source for supplying a solvent to the vapor generation tank 30. When driven by a driving section (not illustrated), the solvent supply section 50 supplies a solvent from a tank (not illustrated) where the solvent is stored to the solvent supply pipe 51. When the on-off valve 74 provided in the solvent supply pipe 51 is in an open state, this allows the solvent supplied from the solvent supply section 50 to be supplied to the vapor generation tank 30 through the solvent supply pipe 51. When the on-off valve 74 is in a closed state, this prevents the solvent from being supplied from the solvent supply section 50 to the vapor generation tank 30 through the solvent supply pipe 51. Examples of the solvent supplied from the solvent supply section 50 may include isopropyl alcohol (IPA) and hydrofluoroether (HFE).

The substrate processing device 100 includes a first inert gas supply pipe 61, which is an example of a second supply pipe. The first inert gas supply pipe 61 connects the vapor generation tank 30 and an inert gas supply section 60 serving as a gas supply source for supplying an inert gas to the vapor generation tank 30. When driven by a driving section (not illustrated), the inert gas supply section 60 supplies the inert gas to the first inert gas supply pipe 61 from a tank (not illustrated) that stores the inert gas. When an on-off valve 76 provided in the first inert gas supply pipe 61 is in an open state, this allows the inert gas supplied from the inert gas supply section 60 to be supplied to the vapor generation tank 30 through the first inert gas supply pipe 61. When the on-off valve 76 is in a closed state, this prevents the inert gas from being supplied from the inert gas supply section 60 to the vapor generation tank 30 through the first inert gas supply pipe 61. Examples of the inert gas supplied by the inert gas supply section 60 may include nitrogen gas (N₂) and argon gas (Ar).

In the first inert gas supply pipe 61, a pressure control regulator 62 is provided. The pressure control regulator 62 regulates the flow rate of the inert gas supplied to the vapor generation tank 30 via the first inert gas supply pipe 61. The pressure control regulator 62 is an example of a regulator. The pressure control regulator 62 may be, for example, an electro-pneumatic regulator. The pressure control regulator 62 is provided downstream of the on-off valve 76 in the first inert gas supply pipe 61. That is, the pressure control regulator 62 is located in the first inert gas supply pipe 61 between the on-off valve 76 and the vapor generation tank 30.

As illustrated in FIG. 2, the pressure control regulator 62 is provided with a pressure sensor 63. The pressure sensor 63 measures the pressure inside the vapor generation tank 30. The pressure sensor 63 measures the absolute pressure inside the vapor generation tank 30. According to the present embodiment, the pressure inside the vapor generation tank 30 is calculated based on the pressure measured by the pressure sensor 63. According to the present embodiment, the pressure sensor 63 measures the pressure inside the first inert gas supply pipe 61. More specifically, the pressure sensor 63 measures the pressure within a pipe inside the pressure control regulator 62 through which the inert gas passes. Here, the pressure sensor 63 is not limited to a device that measures the absolute pressure inside the vapor generation tank 30.

The pressure control regulator 62 regulates the flow rate of the inert gas supplied to the vapor generation tank 30 based on the pressure inside the vapor generation tank 30 measured by the pressure sensor 63. More specifically, the pressure control regulator 62 regulates the flow rate of the inert gas supplied to the vapor generation tank 30 to regulate the pressure measured by the pressure sensor 63 to a target value. The pressure control regulator 62 performs feedback control based on the measurement results of the pressure sensor 63.

The pressure sensor 63 is not limited to the configuration in which the pressure sensor 63 is provided in the pressure control regulator 62. The pressure sensor 63 may be a separate device from the pressure control regulator 62. In this case, it may be configured so that the pressure sensor 63 is provided in the vapor generation tank 30 and the pressure control regulator 62 is provided in the first inert gas supply pipe 61.

Returning to FIG. 1, the substrate processing device 100 may include a second inert gas supply pipe 65. The second inert gas supply pipe 65 connects the inert gas supply section 60 and the gas supply pipe 31. When an on-off valve 78 provided in the second inert gas supply pipe 65 is in an open state, this allows the inert gas to be supplied from the inert gas supply section 60 to the gas supply pipe 31 through the second inert gas supply pipe 65. When the on-off valve 78 is in a closed state, this prevents the inert gas from being supplied from the inert gas supply section 60 to the gas supply pipe 31 through the second inert gas supply pipe 65.

The heater 86 is provided in the second inert gas supply pipe 65 and heats the interior of the second inert gas supply pipe 65. The heater 86 regulates the temperature of the inert gas flowing through the second inert gas supply pipe 65. The heater 86 is located in the second inert gas supply pipe 65 between the on-off valve 78 and the connection point where the second inert gas supply pipe 65 and the gas supply pipe 31 are connected.

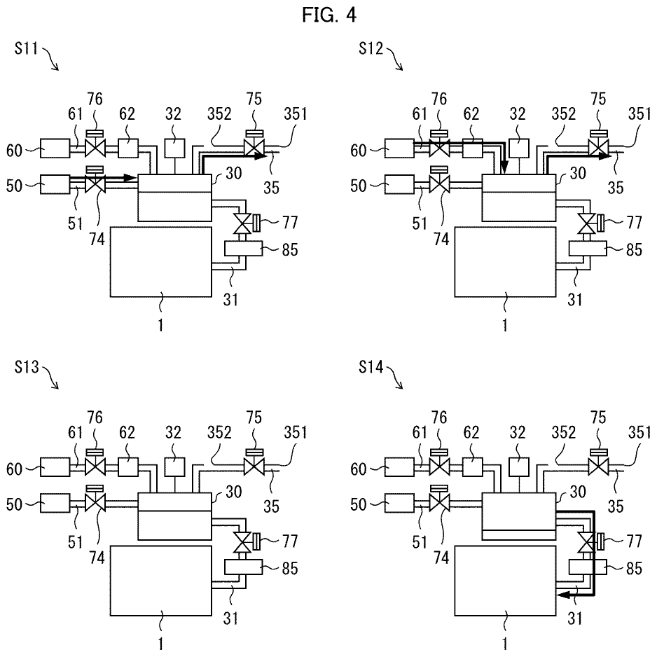

The substrate processing device 100 includes a tank exhaust pipe 35 and an on-off valve 75. The tank exhaust pipe 35, which is connected to the vapor generation tank 30, is provided with the on-off valve 75. The tank exhaust pipe 35 is an example of an exhaust pipe, and the on-off valve 75 is an example of an exhaust device. The tank exhaust pipe 35 has a first exhaust port 351 (see FIG. 4) and a second exhaust port 352 (see FIG. 4) configured to allow a gas inside the vapor generation tank 30 to be discharged to the outside. When the on-off valve 75 is in an open state, this allows the gas inside the vapor generation tank 30 to be discharged to the outside through the first exhaust port 351. When the on-off valve 75 is in a closed state, this prevents the gas inside the vapor generation tank 30 from being discharged to the outside through the first exhaust port 351. The second exhaust port 352 allows the gas inside the vapor generation tank 30 to be discharged to the outside regardless of whether the on-off valve 75 is in an open or closed state.

The second exhaust port 352 has a smaller opening diameter than the first exhaust port 351. The opening diameter of the second exhaust port 352 is set to a dimension capable of regulating the pressure inside the vapor generation tank 30. The opening diameter of the first exhaust port 351 is set to a dimension that makes it impossible to regulate the pressure inside the vapor generation tank 30. For example, the opening diameter of the first exhaust port 351 is approximately 6 mm to 8 mm, and that of the second exhaust port 352 is approximately 3 mm.

As illustrated in FIG. 2, the substrate processing device 100 further includes a controller 90. The controller 90 includes a processor 91 that performs various computations according to programs, and a memory 92 that stores various information such as programs. The processor 91 executes various processes according to programs pre-stored in the memory 92. Examples of the processor 91 may include a central processing unit (CPU), a digital signal processor (DSP), a graphics processing unit (GPU), and a micro processing unit (MPU). Examples of the memory 92 may include read-only memory (ROM), random access memory (RAM), flash memory, and a hard disk drive (HDD).

The controller 90 controls each section of the substrate processing device 100. The controller 90 controls the lifter 5, the chamber pressure sensor 8, the processing liquid supply section 20, the exhaust pump 26, the heater 34, the vacuum gauge 32, the solvent supply section 50, the inert gas supply section 60, the pressure control regulator 62, the on-off valves 70 to 80, and the heaters 85 and 86.

### [Operation of Substrate Processing Device]

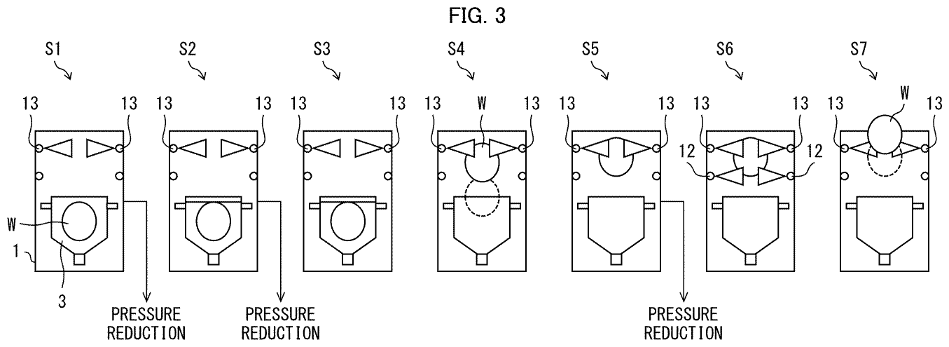

Next, referring to FIG. 3, the operation of the substrate processing device 100 controlled by the controller 90 during the processing of the substrate W will be described. FIG. 3 is a diagram for explaining the operation of the substrate processing device 100. In FIG. 3, for the sake of clarity in the drawing, only the main components of the substrate processing device 100 are illustrated, while other components are omitted. Additionally, in FIG. 3, for the sake of clarity in the drawing, some reference symbols assigned to the illustrated components may be omitted.

As illustrated in FIG. 3, in step S1, a process of immersing the substrate W in the processing liquid is performed. In step S1, the processor 91 moves the lifter 5 to the dipping position 5A to immerse the substrate W in the processing liquid in the processing tank 3. In step S1, the processor 91 fills the chamber 1 with the inert gas after immersing the substrate W in the processing liquid. More specifically, the processor 91 controls the on-off valves 78 and 79 to be in the open states, while controlling the on-off valves 77 and 80 to be in the closed states. In step S1, the processor 91 drives the inert gas supply section 60 for a predetermined period of time. As a result, the inert gas is supplied into the chamber 1 from the nozzle 13, and the inert gas fills the chamber 1. In step S1, the processor 91 reduces the pressure inside the chamber 1 after filling the chamber 1 with the inert gas. More specifically, the processor 91 drives the exhaust pump 26 for a predetermined period of time to discharge the gas inside the chamber 1 to the outside.

In step S2, a process of supplying the solvent vapor into the chamber 1 while reducing the pressure inside the chamber 1 is performed. In step S2, the processor 91 controls the on-off valves 77 and 79 to be in the open states, while controlling the on-off valves 78 and 80 to be in the closed states. As a result, the solvent vapor stored in the vapor generation tank 30 is sent to the nozzle 13 through the gas supply pipe 31 and supplied into the chamber 1 from the nozzle 13. In step S2, the processor 91 drives the exhaust pump 26 for a predetermined period of time to discharge the gas inside the chamber 1 to the outside. In step S2, the processor 91 may optionally drive the heater 85. By driving the heater 85, it is preferable that the temperature of the solvent vapor passing through the gas supply pipe 31 is regulated.

In step S3, performed is a process in which the reduction of the pressure inside the chamber 1 is stopped and the supply of a solvent vapor into the chamber 1 via the nozzle 13 is continued. In step S3, the processor 91 stops driving the exhaust pump 26 and thereby stops the discharge of the gas from the chamber 1. In step S3, the processor 91 continues to control the on-off valves 77 and 79 to remain in the open states, while continuing to control the on-off valves 78 and 80 to remain in the closed states. Additionally, in step S3, the processor 91 may optionally continue driving the heater 85.

In step S4, a process of moving the substrate W out of the processing tank 3 while continuing the supply of the solvent vapor into the chamber 1 via the nozzle 13 is performed. In step S4, the processor 91 moves the lifter 5 to the drying position 5B. As a result, the substrate W is located outside the processing tank 3. In step S4, the supply of the solvent vapor into the chamber 1 via the nozzle 13 is continued. That is, the processor 91 continues to control the on-off valves 77 and 79 to remain in the open states, while continuing to control the on-off valves 78 and 80 to remain in the closed states. Additionally, in step S4, the processor 91 may optionally continue driving the heater 85.

In step S5, a process of drying the substrate W is performed. In step S5, the processor 91 dries the substrate W while supplying the inert gas into the chamber 1. More specifically, in step S5, the processor 91 controls the on-off valves 78 and 79 to be in the open states, while controlling the on-off valves 77 and 80 to be in the closed states. In step S5, the processor 91 drives the inert gas supply section 60. As a result, the inert gas is supplied into the chamber 1 from the nozzle 13. In step S5, the processor 91 drives the exhaust pump 26 for a predetermined period of time to discharge the gas inside the chamber 1 to the outside. In step S5, the processor 91 maintains the lifter 5 in the drying position 5B. Additionally, in step S5, the processor 91 stops driving the heater 85.

In step S6, a process of bringing the pressure inside the chamber 1 to atmospheric pressure is performed. In step S6, the processor 91 controls the on-off valves 78, 79, and 80 to be in the open states, while controlling the on-off valve 77 to be in the closed state. As a result, the inert gas is supplied into the chamber 1 from the nozzles 12 and 13. In step S6, the processor 91 stops driving the exhaust pump 26. As a result, the pressure inside the chamber 1 is brought to atmospheric pressure.

In step S7, a process of transporting the substrate W out of the chamber 1 is performed. In step S7, the processor 91 moves the lifter 5 to the retrieval position 5C. In step S7, the processor 91 controls the on-off valves 78 and 79 to be in the open states, while controlling the on-off valves 77 and 80 to be in the closed states. As a result, the substrate W is transported out of the chamber 1 while the inert gas is being supplied into the chamber 1 from the nozzle 13.

Next, referring to FIG. 4, the operation of the substrate processing device 100 controlled by the controller 90 during the supply of the solvent vapor into the chamber 1 in the abovementioned steps S2 to S4 will be explained. FIG. 4 is a diagram for explaining the operation of the substrate processing device 100. In FIG. 4, for the sake of clarity in the drawing, only the main components of the substrate processing device 100 are illustrated, while other components are omitted.

As illustrated in FIG. 4, in step S11, a solvent supply process of supplying the solvent to the vapor generation tank 30 via the solvent supply pipe 51 is performed. In step S11, the processor 91 controls the on-off valve 74 to be in the open state and drives the solvent supply section 50. As a result, the solvent is supplied to the vapor generation tank 30 from the solvent supply section 50 through the solvent supply pipe 51 and is stored in the vapor generation tank 30. In step S11, the processor 91 stops driving the solvent supply section 50 after a predetermined period of time has elapsed.

Additionally, in step S11, the processor 91 controls the on-off valve 75 to be in the open state. As a result, while the solvent is being supplied into the vapor generation tank 30, the gas inside the vapor generation tank 30 is discharged to the outside through the first exhaust port 351 of the tank exhaust pipe 35. In step S11, the pressure inside the vapor generation tank 30 is more susceptible to atmospheric pressure. In step S11, the processor 91 controls the on-off valves 76 and 77 to be in the closed states.

In step S12, a gas supply process of supplying the inert gas to the vapor generation tank 30 through the first inert gas supply pipe 61 is performed. In step S12, the processor 91 controls the on-off valve 76 to be in the open state and drives the inert gas supply section 60. As a result, the inert gas is supplied from the inert gas supply section 60 to the vapor generation tank 30 through the first inert gas supply pipe 61, and the inert gas is stored in the vapor generation tank 30.

In step S12, the processor 91 stops driving the inert gas supply section 60 and stops supplying the inert gas to the vapor generation tank 30 when the pressure measured by the pressure sensor 63 reaches the target value. In step S12, the processor 91 performs feedback control on the pressure control regulator 62 based on the measurement results of the pressure sensor 63. This enables the regulation of the flow rate of the inert gas supplied to the vapor generation tank 30, which stores the solvent, through the first inert gas supply pipe 61.

Additionally, in step S12, the processor 91 controls the on-off valve 75 to be in the open state. As a result, while the inert gas is being supplied into the vapor generation tank 30, the gas inside the vapor generation tank 30 is discharged to the outside through the first exhaust port 351 of the tank exhaust pipe 35. Further, in step S11, the processor 91 controls the on-off valves 74 and 77 to be in the closed states.

In step S13, a temperature regulating process of regulating the temperature inside the vapor generation tank 30 using the heater 34 is performed. Step S13 is performed after the supply of the inert gas is stopped, that is, after the inert gas supply section 60 is stopped. In step S13, the processor 91 drives the heater 34 to heat the interior of the vapor generation tank 30 for a predetermined period of time. In step S13, the processor 91 controls the on-off valve 75 to be in the closed state. This causes the gas inside the vapor generation tank 30 not to be discharged to the outside through the first exhaust port 351 of the tank exhaust pipe 35 while the temperature of the interior of the vapor generation tank 30 is regulated. Further, in step S13, the processor 91 controls the on-off valves 74 to 77 to be in the closed states.

In step S14, a vapor supply process of supplying the solvent vapor from the vapor generation tank 30 to the chamber 1 through the gas supply pipe 31 is performed. Step S14 is performed after the supply of the inert gas is stopped, that is, after the inert gas supply section 60 is stopped. Additionally, in step S14, the temperature-regulated solvent vapor is supplied from the vapor generation tank 30 to the chamber 1.

In step S14, the processor 91 controls the on-off valve 77 to be in the open state. As a result, since the pressure inside the chamber 1 is reduced in the abovementioned step S1, the solvent vapor is supplied from the vapor generation tank 30 to the chamber 1. In step S14, the processor 91 controls the on-off valves 74 to 76 to be in the closed states.

Here, step S12 is performed after the exhaust pump 26 is driven in the abovementioned step S1 to reduce the pressure inside the chamber 1. Each of steps S12 and S13 is executed at a timing determined by back-calculating from the scheduled stop time at which the drive of the exhaust pump 26 in step S1 is stopped.

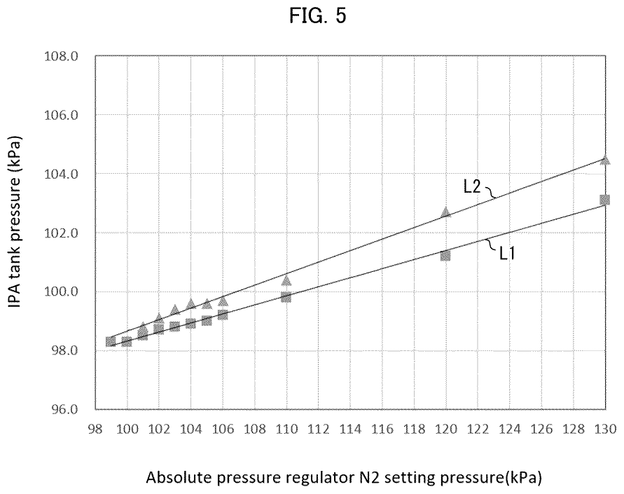

Next, referring to FIGS. 5 to 8, the experimental results regarding the pressure regulation inside the vapor generation tank 30 and the pressure changes inside the vapor generation tank 30 will be explained. In the experiments depicted in FIGS. 5 to 8, IPA was used as the solvent stored in the vapor generation tank 30, and N₂ gas was used as the inert gas supplied to the vapor generation tank 30.

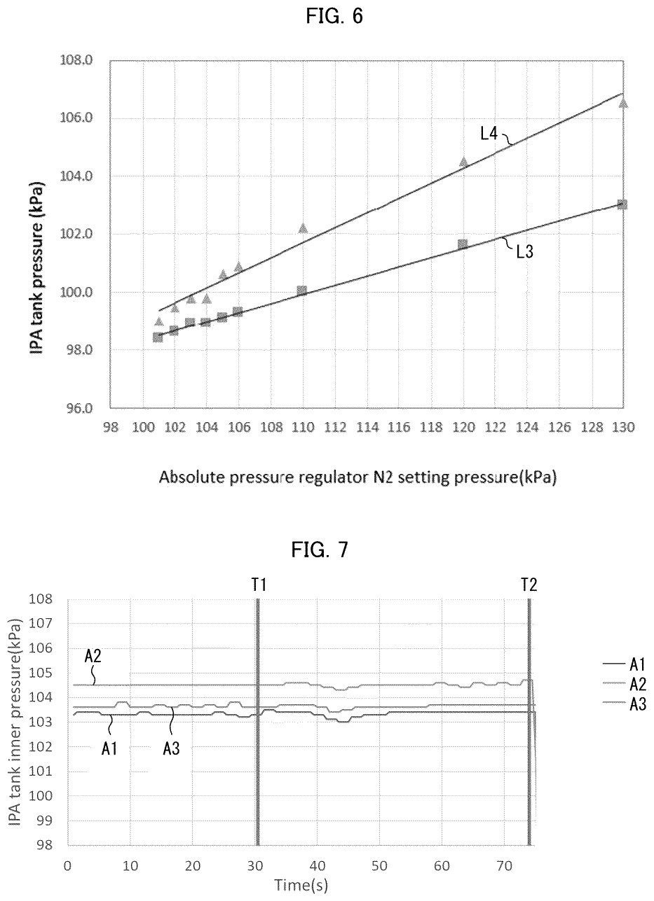

First, the experimental results regarding the pressure regulation inside the vapor generation tank 30 will be explained. FIGS. 5 and 6 are graphs showing the results of experiments in which the pressure inside the vapor generation tank 30 and the pressure inside the first inert gas supply pipe 61, as measured by the pressure sensor 63 of the pressure control regulator 62, were measured. In the experiments shown in FIGS. 5 and 6, the pressure inside the vapor generation tank 30 was measured using a sensor different from the pressure sensor 63. In each of FIGS. 5 and 6, the vertical axis of the graph represents the pressure value (kPa) inside the vapor generation tank 30. In each of FIGS. 5 and 6, the horizontal axis of the graph represents the pressure value inside the first inert gas supply pipe 61 measured by the pressure sensor 63 of the pressure control regulator 62, indicating the target pressure value (kPa) inside the first inert gas supply pipe 61. The pressure values in the graphs of FIGS. 5 and 6 are absolute pressures.

In the experiment shown in FIG. 5, the pressure control regulator 62 was feedback-controlled for 37 seconds so that the pressure value measured by the pressure sensor 63 reached the target value, after which the pressure inside the vapor generation tank 30 was measured. Solid line L1 in the graph of FIG. 5 represents the relationship between the pressure value inside the vapor generation tank 30 immediately after the feedback control of the pressure control regulator 62 for 37 seconds and the target pressure value inside the first inert gas supply pipe 61. Solid line L2 in the graph of FIG. 5 represents the relationship between the pressure value inside the vapor generation tank 30 immediately after regulation of the temperature inside the vapor generation tank 30 for 5 seconds following the 37-second feedback control of the pressure control regulator 62 and the target pressure value inside the first inert gas supply pipe 61. As shown by the solid lines L1 and L2, the pressure inside the vapor generation tank 30 increased linearly in proportion to the rise in the pressure inside the first inert gas supply pipe 61.

In the experiment shown in FIG. 6, the pressure control regulator 62 was feedback-controlled for 22 seconds so that the pressure value measured by the pressure sensor 63 reached the target value, after which the pressure inside the vapor generation tank 30 was measured. Solid line L3 in the graph of FIG. 6 represents the relationship between the pressure value inside the vapor generation tank 30 immediately after the feedback control of the pressure control regulator 62 for 22 seconds and the target pressure value inside the first inert gas supply pipe 61. Solid line L4 in the graph of FIG. 6 represents the relationship between the pressure value inside the vapor generation tank 30 immediately after regulation of the temperature inside the vapor generation tank 30 for 20 seconds following the 22-second feedback control of the pressure control regulator 62 and the target pressure value inside the first inert gas supply pipe 61. As shown by the solid lines L3 and L4, even when the feedback control time was shortened and the temperature regulation time inside the vapor generation tank 30 was extended, the pressure inside the vapor generation tank 30 increased linearly in proportion to the rise in the pressure inside the first inert gas supply pipe 61.

From the experimental results shown in FIGS. 5 and 6, it was found that the pressure inside the vapor generation tank 30 changes linearly in proportion to the changes in the pressure inside the first inert gas supply pipe 61. From these experimental results, it was found that the pressure inside the vapor generation tank 30 can be measured based on the pressure inside the first inert gas supply pipe 61.

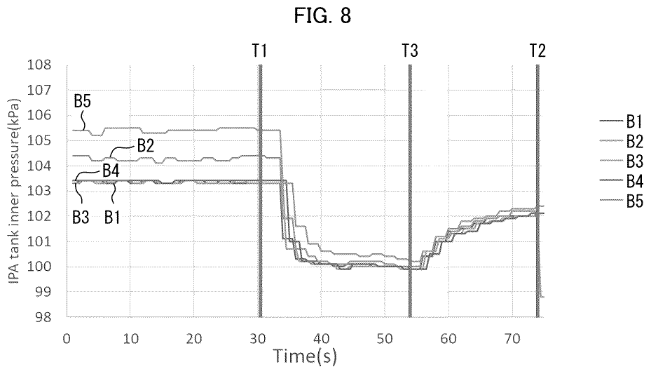

Next, the experimental results regarding the pressure changes inside the vapor generation tank 30 will be explained. FIGS. 7 and 8 are graphs each showing the pressure changes inside the vapor generation tank 30. In each of FIGS. 7 and 8, the vertical axis of the graph represents the pressure value (kPa) inside the vapor generation tank 30. In each of FIGS. 7 and 8, the horizontal axis of the graph represents the elapsed time (S) since the start of IPA supply to the vapor generation tank 30. The pressure values inside the vapor generation tank 30 shown in FIGS. 7 and 8 are absolute pressures. In FIGS. 7 and 8, the timing when the pressure reduction of chamber 1 begins is indicated as timing T1, and the timing when the supply of IPA vapor to the chamber 1 begins is indicated as timing T2, both represented by solid lines.

The graph in FIG. 7 shows the pressure changes inside the vapor generation tank 30 when no pressure regulation was performed in the vapor generation tank 30. Samples A1 to A3 shown in the graph of FIG. 7 represent the results of experiments conducted under different atmospheric pressure conditions. Sample A1 represents the data from the experiment conducted under the experimental condition with the lowest atmospheric pressure among the experimental environments of samples A1 to A3. Sample A2 represents the data from the experiment conducted under the experimental condition with the highest atmospheric pressure among the experimental environments of samples A1 to A3.

As shown in the graph of FIG. 7, at the start of IPA supply to the vapor generation tank 30, the pressure value inside the vapor generation tank 30 for each sample A1 to A3 is influenced by the atmospheric pressure of the experimental environment, resulting in a value approximately equal to the atmospheric pressure of the respective experimental conditions. Thus, at the start of IPA supply to the vapor generation tank 30, the pressure value inside the vapor generation tank 30 for each sample A1 to A3 varies. In particular, there is a large pressure difference between sample A1, which has the lowest pressure value inside the vapor generation tank 30, and sample A2, which has the highest pressure value inside the vapor generation tank 30.

For each of samples A1 to A3, it was found that while the pressure value inside the vapor generation tank 30 shows slight fluctuations from the start of IPA supply to the vapor generation tank 30 until timing T2, the pressure value inside the vapor generation tank 30 does not largely changed between the start of IPA supply and timing T2. That is, it was found that at timing T2, the pressure value inside the vapor generation tank 30 for each sample A1 to A3 varies.

The graph in FIG. 8 shows the pressure changes inside the vapor generation tank 30 when pressure regulation was performed in the vapor generation tank 30. Samples B1 to B5 shown in the graph of FIG. 8 represent the results of experiments conducted under various experimental conditions. Samples B1, B3, and B4 represent the results of the experiments conducted under experimental conditions where the atmospheric pressure was approximately the same. Sample B5 represents the data from the experiment conducted under the experimental condition with the highest atmospheric pressure among the experimental environments of samples B1 to B5. Sample B2 represents the result of the experiment conducted under an experimental condition with an atmospheric pressure different from that of samples B1 and B3 to B5.

As shown in the graph of FIG. 8, at the start of IPA supply to the vapor generation tank 30, the pressure value inside the vapor generation tank 30 for each sample B1 to B5 is influenced by the atmospheric pressure of the experimental environment, resulting in a value approximately equal to the atmospheric pressure of the respective experimental conditions. Thus, at the start of IPA supply to the vapor generation tank 30, the pressure value inside the vapor generation tank 30 for each samples B1 to B5 varies. In particular, there is a large pressure difference between samples B1, B3, and B4, which have the lowest pressure values inside the vapor generation tank 30, and sample B5, which has the highest pressure value in the vapor generation tank 30.

As shown in the graph of FIG. 8, after timing T1, the supply amount of N₂ gas supplied to the vapor generation tank 30 is regulated to regulate the pressure inside the vapor generation tank 30. Thus, at timing T3 at which the supply of N₂ gas was stopped after the completion of the pressure regulation inside the vapor generation tank 30, the variation in the pressure values inside the vapor generation tank 30 among samples B1 to B5 decreased. In particular, the pressure difference between samples B1, B3, and B4, and sample B5 was reduced. During the period between timing T3 and timing T2, the temperature regulation was performed in the vapor generation tank 30, so that the pressure values inside the vapor generation tank 30 in each of samples B1 to B5 increased. At timing T2, the variation in the pressure values inside the vapor generation tank 30 for each sample B1 to B5 became smaller than the variation in the pressure values inside the vapor generation tank 30 for each sample B1 to B5 at the start of IPA supply.

From the experimental results shown in FIG. 7, at timing T2, the pressure inside the vapor generation tank 30 varied due to the influence of atmospheric pressure. Thus, it is considered that the variation in pressure inside the vapor generation tank 30 leads to a variation in the IPA concentration of the IPA vapor generated within the vapor generation tank 30. That is, the variation in IPA concentration also occurs in the IPA vapor supplied to the chamber 1. From the experimental results shown in FIG. 8, it was found that temporarily stopping the supply of the inert gas after the pressure regulation inside the vapor generation tank 30 reduced the variation in pressure inside the vapor generation tank 30, even under various atmospheric pressure conditions. Thus, it was suggested that this approach makes it less likely for variations to occur in the IPA concentration of the IPA vapor generated within the vapor generation tank 30. That is, it was suggested that this approach makes it less likely for variations to occur in the IPA concentration of the IPA vapor supplied to the chamber 1.

As described above, according to the substrate processing device 100, the supply of the inert gas is temporarily stopped after the pressure inside the vapor generation tank 30 reaches the target value. After that, the solvent vapor is supplied from the vapor generation tank 30 to the chamber 1. Even if changes occur in atmospheric pressure, the vapor generation tank 30 is pressure-regulated, making it possible to reduce variations in the solvent concentration of the solvent vapor supplied from the vapor generation tank 30 to the chamber 1. This makes it possible to stabilize the solvent concentration of the solvent vapor supplied to the chamber 1.

According to the abovementioned substrate processing device 100, after the temperature inside the vapor generation tank 30 is regulated, the solvent vapor regulated in temperature is supplied from the vapor generation tank 30 to the chamber 1. Thus, it is possible to prevent the temperature inside the chamber 1 from decreasing due to the solvent vapor supplied from the vapor generation tank 30 to the chamber 1.

According to the substrate processing device 100, by discharging the gas inside the vapor generation tank 30 through the on-off valve 75, it is possible to prevent the pressure inside the vapor generation tank 30 from increasing when the solvent or the inert gas is supplied to the vapor generation tank 30. This makes it possible to appropriately regulate the pressure inside the vapor generation tank 30.

In the substrate processing device 100, while the interior of the vapor generation tank 30 is being temperature-regulated, the gas inside the vapor generation tank 30 is not discharged to the outside because the on-off valve 75 is in the closed state. Therefore, it is possible to prevent the pressure inside the vapor generation tank 30 from becoming equal to the atmospheric pressure. This makes it possible to regulate the temperature while maintaining the pressure inside the vapor generation tank 30.

According to the substrate processing device 100, since the second exhaust port 352 is provided in the tank exhaust pipe 35, the gas inside the vapor generation tank 30 can be discharged through the second exhaust port 352. In addition, the second exhaust port 352 has a smaller opening diameter than the first exhaust port 351. Therefore, even when the gas inside the vapor generation tank 30 is not discharged through the first exhaust port 351 by the on-off valve 75, the interior of the vapor generation tank 30 can be pressure-regulated while discharging the gas inside the vapor generation tank 30 through the second exhaust port 352. This makes it possible to regulate the temperature inside the vapor generation tank 30 while pressure-regulating the interior of the vapor generation tank 30.

According to the substrate processing device 100, a pressure sensor 63 is provided in the first inert gas supply pipe 61. Therefore, the pressure sensor 63 can be easily provided in the substrate processing device 100. For example, the pressure sensor 63 can be retrofitted to the existing substrate processing device 100.

### Summary

A substrate processing device in accordance with an aspect of the present invention is a substrate processing device configured to dry, using a solvent vapor, a substrate processed with a processing liquid, the substrate processing device including: a processing tank configured to store a processing liquid; a chamber enclosing the processing tank; a pressure reduction device configured to discharge a gas inside the chamber to reduce pressure inside the chamber; a vapor generation tank configured to store a solvent and to generate vapor of the solvent as the solvent vapor; a first supply pipe connecting the chamber and the vapor generation tank; a second supply pipe connecting the vapor generation tank and a gas supply source configured to supply an inert gas to the vapor generation tank; a pressure sensor configured to measure pressure inside the vapor generation tank; a regulator configured to regulate flow rate of the inert gas supplied to the vapor generation tank; and a controller, the controller being configured to carry out: a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and a vapor supply process of supplying the solvent vapor from the vapor generation tank to the chamber through the first supply pipe after the supply of the inert gas is stopped.

In the substrate processing device in accordance with an aspect of the present invention, the substrate processing device may have a configuration of further including a heating device configured to heat an interior of the vapor generation tank, wherein the controller is further configured to carry out a temperature regulating process of regulating, using the heating device, temperature of the interior of the vapor generation tank after the supply of the inert gas is stopped, and in the vapor supply process, the controller causes the temperature-regulated solvent vapor to be supplied from the vapor generation tank to the chamber.

In the substrate processing device in accordance with an aspect of the present invention, the substrate processing device may have a configuration of further including: a third supply pipe connecting the vapor generation tank and a solvent supply source configured to supply the solvent to the vapor generation tank; and an exhaust device configured to discharge a gas inside the vapor generation tank to outside, wherein the controller is further configured to carry out a solvent supply process of supplying the solvent to the vapor generation tank through the third supply pipe, and in the solvent supply process and the gas supply process, the controller controls the exhaust device to discharge a gas inside the vapor generation tank to outside.

In the substrate processing device in accordance with an aspect of the present invention, the substrate processing device may have a configuration in which in the temperature regulating process, the controller controls the exhaust device so that a gas inside the vapor generation tank is not discharged to outside.

In the substrate processing device in accordance with an aspect of the present invention, the substrate processing device may have a configuration in which the exhaust device is provided in an exhaust pipe connected to the vapor generation tank, and the exhaust pipe has a first exhaust port configured to allow a gas inside the vapor generation tank to be discharged to outside and a second exhaust port configured to allow a gas inside the vapor generation tank to be discharged to outside, the second exhaust port having a smaller opening diameter than the first exhaust port.

In the substrate processing device in accordance with an aspect of the present invention, the substrate processing device may have a configuration in which the pressure sensor is provided in the second supply pipe.

A method of processing a substrate in accordance with an aspect of the present invention is a control method of a substrate processing device configured to dry, using a solvent vapor, a substrate processed with a processing liquid, the substrate processing device including: a processing tank configured to store a processing liquid; a chamber enclosing the processing tank; a pressure reduction device configured to discharge a gas inside the chamber to reduce pressure inside the chamber; a vapor generation tank configured to store a solvent and to generate vapor of the solvent as the solvent vapor; a first supply pipe connecting the chamber and the vapor generation tank; a second supply pipe connecting the vapor generation tank and a gas supply source configured to supply an inert gas to the vapor generation tank; a pressure sensor configured to measure pressure inside the vapor generation tank; and a regulator configured to regulate flow rate of the inert gas supplied to the vapor generation tank, the method including: a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and a vapor supply process of supplying the solvent vapor from the vapor generation tank to the chamber through the first supply pipe after the supply of the inert gas is stopped.

### REFERENCE SIGNS LIST

1 Chamber
3 Processing tank
26 Exhaust pump (pressure reduction device)
30 Vapor generation tank
31 Gas supply pipe (first supply pipe)
34 Heater (heating device)
35 Tank exhaust pipe
51 Solvent supply pipe (third supply pipe)
61 First inert gas supply pipe (second supply pipe)
62 Pressure control regulator (regulator)
63 Pressure sensor
90 Controller
100 Substrate processing device
351 First exhaust port
352 Second exhaust port

1. A substrate processing device configured to dry, using a solvent vapor, a substrate processed with a processing liquid, the substrate processing device comprising:
a processing tank configured to store a processing liquid;
a chamber enclosing the processing tank;
a pressure reduction device configured to discharge a gas inside the chamber to reduce pressure inside the chamber;
a vapor generation tank configured to store a solvent and to generate vapor of the solvent as the solvent vapor;
a first supply pipe connecting the chamber and the vapor generation tank;
a second supply pipe connecting the vapor generation tank and a gas supply source configured to supply an inert gas to the vapor generation tank;
a pressure sensor configured to measure pressure inside the vapor generation tank;
a regulator configured to regulate flow rate of the inert gas supplied to the vapor generation tank; and
a controller,
the controller being configured to carry out:
a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and
a vapor supply process of supplying the solvent vapor from the vapor generation tank to the chamber through the first supply pipe after the supply of the inert gas is stopped.

2. The substrate processing device according to claim 1, further comprising a heating device configured to heat an interior of the vapor generation tank,
wherein the controller is further configured to carry out a temperature regulating process of regulating, using the heating device, temperature of the interior of the vapor generation tank after the supply of the inert gas is stopped, and
in the vapor supply process, the controller causes the temperature-regulated solvent vapor to be supplied from the vapor generation tank to the chamber.

3. The substrate processing device according to claim 2, further comprising:
a third supply pipe connecting the vapor generation tank and a solvent supply source configured to supply the solvent to the vapor generation tank; and
an exhaust device configured to discharge a gas inside the vapor generation tank to outside,
wherein the controller is further configured to carry out a solvent supply process of supplying the solvent to the vapor generation tank through the third supply pipe, and
in the solvent supply process and the gas supply process, the controller controls the exhaust device to discharge a gas inside the vapor generation tank to outside.

4. The substrate processing device according to claim 3, wherein in the temperature regulating process, the controller controls the exhaust device so that a gas inside the vapor generation tank is not discharged to outside.

5. The substrate processing device according to claim 3, wherein the exhaust device is provided in an exhaust pipe connected to the vapor generation tank, and
the exhaust pipe has a first exhaust port configured to allow a gas inside the vapor generation tank to be discharged to outside and a second exhaust port configured to allow a gas inside the vapor generation tank to be discharged to outside, the second exhaust port having a smaller opening diameter than the first exhaust port.

6. The substrate processing device according to claim 1, wherein the pressure sensor is provided in the second supply pipe.

7. A control method of a substrate processing device configured to dry, using a solvent vapor, a substrate processed with a processing liquid, the substrate processing device including: a processing tank configured to store a processing liquid; a chamber enclosing the processing tank; a pressure reduction device configured to discharge a gas inside the chamber to reduce pressure inside the chamber; a vapor generation tank configured to store a solvent and to generate vapor of the solvent as the solvent vapor; a first supply pipe connecting the chamber and the vapor generation tank; a second supply pipe connecting the vapor generation tank and a gas supply source configured to supply an inert gas to the vapor generation tank; a pressure sensor configured to measure pressure inside the vapor generation tank; and a regulator configured to regulate flow rate of the inert gas supplied to the vapor generation tank,
the method comprising:
a gas supply process of controlling the regulator based on the pressure measured by the pressure sensor to regulate the flow rate of the inert gas supplied through the second supply pipe to the vapor generation tank in which the solvent is stored, and to stop the supply of the inert gas when the pressure measured by the pressure sensor reaches a target value; and
a vapor supply process of supplying the solvent vapor from the vapor generation tank to the chamber through the first supply pipe after the supply of the inert gas is stopped.
